(19) United States
(12) Patent Application Publication
(10) Pub. No.: US 2012/0187553 A1
(43) Pub. Date: Jul. 26, 2012

(54) METHOD OF MANUFACTURING SEMICONDUCTOR WAFER BONDING PRODUCT, SEMICONDUCTOR WAFER BONDING PRODUCT AND SEMICONDUCTOR DEVICE

(75) Inventors: Masahiro Yoneyama, Shinagawa-ku (JP); Masakazu Kawata, Shinagawa-ku (JP); Toyosei Takahashi, Shinagawa-ku (JP); Hirohisa Dejima, Shinagawa-ku (JP); Fumihiro Shiraishi, Shinagawa-ku (JP); Toshihiro Sato, Shinagawa-ku (JP)

(73) Assignee: SUMITOMO BAKELITE COMPANY LIMITED, Tokyo (JP)

(21) Appl. No.: 13/394,993

(22) PCT Filed: Sep. 8, 2010
(86) PCT No.: PCT/JP2010/065431

§ 371 Date: Mar. 27, 2012

(30) Foreign Application Priority Data
Sep. 9, 2009 (JP) 2009-208705
Sep. 16, 2009 (JP) 2009-215055

(51) Int. Cl. H01L 23/04; H01L 21/50

(52) U.S. Cl. 257/680; 438/116; 257/E23.181; 257/E21.499

(57) ABSTRACT

A method of manufacturing a semiconductor wafer bonding product according to the present invention includes: a step of preparing a spacer formation film including a support base having a sheet-like shape and a spacer formation layer provided on the support base and having photosensitivity; a step of attaching the spacer formation layer to a semiconductor wafer having one surface from a side of the one surface; a step of forming a spacer by subjecting the spacer formation layer to exposure and development to be patterned and removing the support base; and a step of bonding a transparent substrate to a region of the spacer where the removed support base was provided so that transparent substrate is included within the region. This makes it possible to manufacture a semiconductor wafer bonding product in which the semiconductor wafer and the transparent substrate are bonded together through the spacer uniformly and reliably.

### TECHNICAL FIELD

The present invention relates to a method of manufacturing a semiconductor wafer bonding product, a semiconductor wafer bonding product and a semiconductor device.

### RELATED ART

Semiconductor devices represented by photo receiving devices such as a CMOS image sensor and a CCD image sensor are known. In general, such a semiconductor device includes a semiconductor substrate provided with a light receiving portion, a spacer provided on the semiconductor substrate at a side of the light receiving portion and formed so as to surround the light receiving portion, and a transparent substrate bonded to the semiconductor substrate via the spacer.

A method of manufacturing such a semiconductor device generally includes: a step of attaching a bonding film (spacer formation layer) having photosensitivity to a semiconductor wafer on which a plurality of light receiving portions are provided; a step of selectively irradiating the bonding film with a chemical ray via a mask to expose the bonding film; a step of developing the exposed bonding film to form a spacer (spacer substrate); a step of bonding a transparent substrate to the thus formed spacer to obtain a semiconductor product (hereinbelow, it will be referred to as “semiconductor wafer bonding product”); and a step of dicing the semiconductor wafer bonding product to obtain semiconductor devices (see, for example, Patent Document 1).

The bonding film before being attached to the semiconductor wafer is, usually, provided on a sheet-like base. Such a sheet-like base is sucked onto a plate for press, and then, in this state, the sheet-like base and the bonding film are cut along an outer edge of the plate for press. Thereafter, the plate for press is moved above the semiconductor wafer, and then the bonding film is attached to the semiconductor wafer by being pressed through the sheet-like base using the plate for press.

An outer diameter of each of the sheet-like base and the bonding film, which has been cut along the outer edge of the plate for press as described above, is smaller than an outer diameter of the semiconductor wafer. Therefore, in the case where the bonding film is attached to the semiconductor wafer by being pressed through the sheet-like base using the plate for press, the outer edge of the bonding film is extruded beyond the outer edge of the base, so that an extruded portion of the bonding film is formed on the semiconductor wafer.

As a result, a thickness of the extruded portion becomes larger than that of a portion other than the extruded portion (that is, a portion which becomes thin by being pressed).

On the other hand, conventionally, as the transparent substrate to be bonded to the semiconductor wafer, used is a transparent substrate having a size equal to that of the semiconductor wafer or a transparent substrate having a size slightly larger than that of the semiconductor wafer. Therefore, the transparent substrate is bonded to both the thick and thin portions of the bonding film. As a result, there is a case that the transparent substrate is difficult to make close contact with the bonding film uniformly so that partial bonding failure occurs.

In the case where a semiconductor device is manufactured using a semiconductor wafer bonding product having such bonding failure, a yield thereof is reduced.

### PRIOR ART DOCUMENT

### Patent Document

Patent Document 1: JP-A 2008-91399.

### SUMMARY OF THE INVENTION

It is an object of the present invention to provide a method of manufacturing a semiconductor wafer bonding product in which a semiconductor wafer and a transparent substrate are bonded together through a spacer uniformly and reliably, and to provide a semiconductor wafer bonding product and a semiconductor device each having superior reliability.

In order to achieve such an object, the present invention includes the following features (1) to (16).

(1) A method of manufacturing a semiconductor wafer bonding product, comprising:

a step of preparing a spacer formation film including a support base having a sheet-like shape and a spacer formation layer provided on the support base and having photosensitivity;

a step of attaching the spacer formation layer to a semiconductor wafer having one surface from a side of the one surface;

a step of forming a spacer by subjecting the spacer formation layer to exposure and development to be patterned and removing the support base; and

a step of bonding a transparent substrate to a region of the spacer where the removed support base was provided so that transparent substrate is included within the region.

(2) The method according to the above feature (1), wherein in the step of attaching the spacer formation layer to the semiconductor wafer, the spacer formation layer is attached onto the semiconductor wafer so that an outer edge of the spacer formation layer is located beyond an outer edge of the support base.

(3) The method according to the above feature (2) further comprising: a step of sucking the support base to a pressing surface of a pressing member to bring it into a sucked state and cutting the spacer formation film along an outer edge of the pressing surface in the sucked state, before the step of attaching the spacer formation layer to the semiconductor wafer.

(4) The method according to the above feature (3), wherein in the step of attaching the spacer formation layer to the semiconductor wafer, the support base is pressed toward the spacer formation layer by the pressing surface.

(5) The method according to any one of the above features (1) to (4), wherein in the step of attaching the spacer formation layer to the semiconductor wafer, each of the support base and the spacer formation layer has such a size that the transparent substrate can be included within a region of the spacer where the removed support base was provided in the step of bonding the transparent substrate.

(6) The method according to the above feature (5), wherein the semiconductor wafer has a chamfered portion along an outer edge thereof, the chamfered portion formed by chamfering an outer (peripheral) portion of the semiconductor wafer, and

wherein in the step of attaching the spacer formation layer to the semiconductor wafer, the spacer formation layer is attached onto the semiconductor wafer so that an outer edge of the spacer formation layer is located on or near the chamfered portion.

(7) The method according to the above feature (5) or (6), wherein in the step of attaching the spacer formation layer to the semiconductor wafer, the spacer formation layer is attached onto the semiconductor wafer so that an outer edge of the spacer formation layer coincides with or is located beyond an outer edge of the semiconductor wafer.

(8) The method according to any one of the above features (1) to (4), wherein in the step of attaching the spacer formation layer to the semiconductor wafer, the spacer formation layer is attached onto the semiconductor wafer so that an outer edge of the spacer formation layer is located within an outer edge of the semiconductor wafer.

(9) The method according to the above feature (8), wherein in the step of bonding the transparent substrate, the transparent substrate is bonded to the spacer so that an outer edge of the transparent substrate is located within the outer edge of the spacer formation layer.

(10) The method according to any one of the above features (1) to (9), wherein the exposure is carried out by selectively irradiating the spacer formation layer with a chemical ray through the support base before the support base is removed, and the development is carried out after the support base has been removed.

(11) The method according to any one of the above features (1) to (10), wherein an average thickness of the support base is in the range of 5 to 100 μm.

(12) The method according to any one of the above features (1) to (11), wherein the spacer formation layer is formed of a material containing an alkali soluble resin, a thermosetting resin and a photo initiator.

(13) The method according to the above feature (12), wherein the alkali soluble resin is a (meth)acryl-modified phenol resin.

(14) The method according to the above feature (12) or (13), wherein the thermosetting resin is an epoxy resin.

(15) A semiconductor wafer bonding product manufactured using the method according to any one of the above features (1) to (14).

(16) A semiconductor device obtained by dicing the semiconductor wafer bonding product according to the above feature (15).

### BRIEF DESCRIPTION OF THE DRAWINGS

FIG. 1 is a sectional view showing a semiconductor device according to an embodiment of the present invention.

FIG. 2 is a longitudinal sectional view showing a semiconductor wafer bonding product according to the embodiment of the present invention (that is a first embodiment).

FIG. 3 is a top view showing the semiconductor wafer bonding product shown in FIG. 2.

FIG. 4 is a process chart showing one example of a method of manufacturing the semiconductor device shown in FIG. 1 (or the semiconductor wafer bonding product shown in FIG. 2).

FIG. 5 is a process chart showing the one example of the method of manufacturing the semiconductor device shown in FIG. 1 (or the semiconductor wafer bonding product shown in FIG. 2), which is continued from FIG. 4.

FIG. 6 is a view for explaining the attaching process shown in FIG. 4(C).

FIG. 7 is a view for explaining the attaching process shown in FIG. 4(C).

FIG. 8 is a longitudinal sectional view showing a semiconductor wafer bonding product according to the embodiment of the present invention (that is, a second embodiment).

FIG. 9 is a process chart showing one example of a method of manufacturing the semiconductor wafer bonding product shown in FIG. 8.

FIG. 10 is a process chart showing the one example of the method of manufacturing the semiconductor wafer bonding product shown in FIG. 8, which is continued from FIG. 9.

### MODE FOR CARRYING OUT THE INVENTION

Hereinafter, description will be made on embodiments of the present invention based on the accompanying drawings.

### First Embodiment

### Semiconductor Device (Image Sensor)

First, description will be made on a semiconductor device of the present invention.

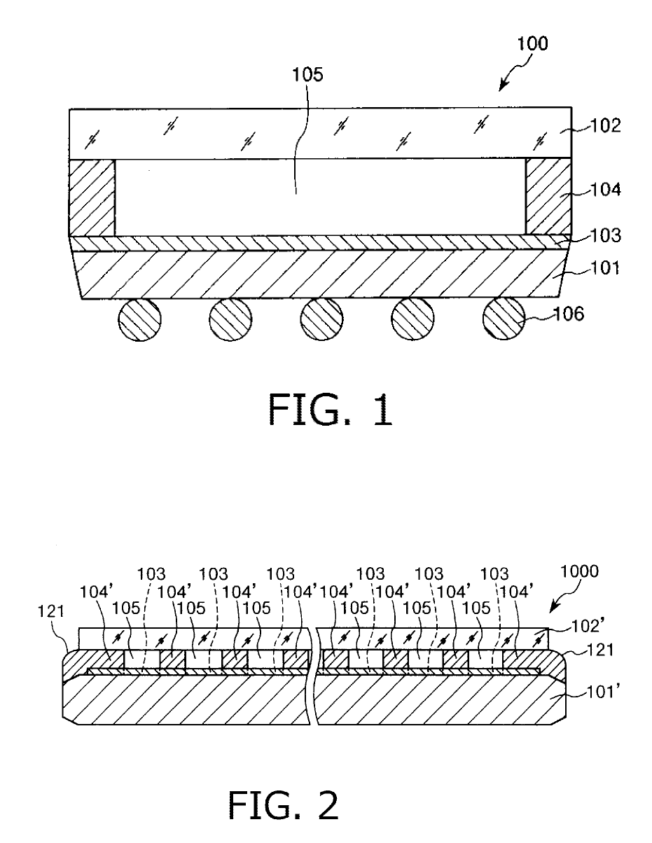

FIG. 1 is a sectional view showing a semiconductor device according to an embodiment of the present invention. In this regard, in the following description, the upper side in FIG. 1 will be referred to as “upper” and the lower side thereof will be referred to as “lower” for convenience of explanation.

A semiconductor device 100 shown in FIG. 1 is obtained by dicing a semiconductor wafer bonding product 1000 of the present invention, which will be described below.

As shown in FIG. 1, such a semiconductor device (light receiving device) 100 includes a base substrate 101, a transparent substrate 102 provided so as to face the base substrate 101, an individual circuit 103 provided on a surface of the base substrate 101, which is located at a side of the transparent substrate 102, and having a light receiving portion, a spacer 104 provided between the transparent substrate and the individual circuit 103 having the light receiving portion, and solder bumps 106 each provided on a surface of the base substrate 101 opposite to the individual circuit 103 having the light receiving portion.

The base substrate 101 is a semiconductor substrate on which the individual circuit 103 (not shown in FIG. 1) is provided. In this regard, as described below, a semiconductor wafer is provided with the individual circuits 103 plurally.

On almost a whole one surface (upper surface) of the base substrate 101, the individual circuit 103 is provided.

For example, the individual circuit 103 having the light receiving portion has a structure in which a light receiving element and a microlens array are formed (stacked) on the base substrate 101 in this order.

Examples of the light receiving element of the individual circuit 103 having the light receiving portion include CCD (Charge Coupled Device), a CMOS (Complementary Metal Oxide Semiconductor) image sensor and the like. Such an individual circuit 103 having the light receiving portion, in which the light receiving element is provided, changes light received by the individual circuit 103 having the light receiving portion to electrical signals.

The transparent substrate 102 is provided so as to face the one surface (upper surface) of the base substrate 101 and has a planar size substantially equal to a planar size of the base substrate 101.

Examples of the transparent substrate 102 include an acryl resin substrate, a polyethylene terephthalate resin (PET) substrate, a glass substrate and the like.

The spacer 104 is directly bonded to both the individual circuit 103 having the light receiving portion and the transparent substrate 102. In this way, the base substrate 101 and the transparent substrate 102 are bonded together through the spacer 104.

Further, the spacer 104 is provided along an outer edge portion of each of the individual circuit 103 having the light receiving portion and the transparent substrate 102, to thereby be of a frame shape. In this way, an air-gap portion 105 is formed (defined) between the individual circuit 103 having the light receiving portion and the transparent substrate 102.

Here, the spacer 104 is provided so as to surround a central area of the individual circuit 103 having the light receiving portion. Therefore, an area of the individual circuit 103 having the light receiving portion surrounded by the spacer 104, that is, an area exposed within the air-gap portion 105 can substantially function as a light receiving portion.

The solder bumps 106 have conductivity and are electrically connected to a circuit provided on the lower surface of the base substrate 101. This makes it possible for the electrical signals changed from the light by the individual circuit 103 having the light receiving portion to be transmitted to the solder bumps 106.

<Semiconductor Wafer Bonding Product>

Next, description will be made on a semiconductor wafer bonding product.

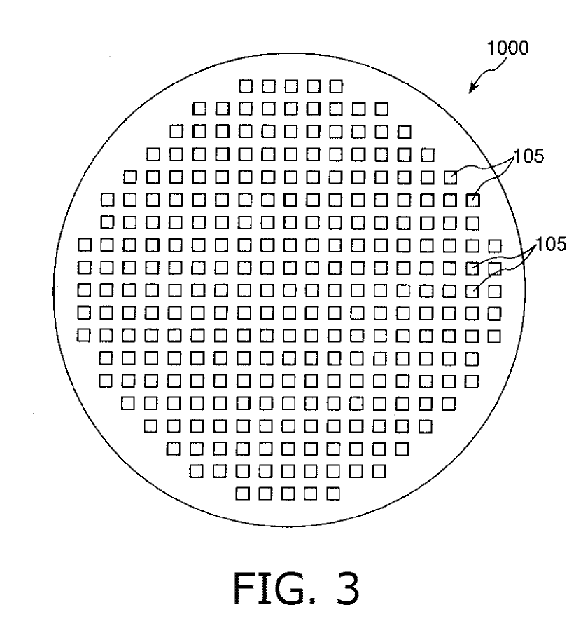

FIG. 2 is a longitudinal sectional view showing the semiconductor wafer bonding product according to the embodiment of the present invention, and FIG. 3 is a top view showing the semiconductor wafer bonding product shown in FIG. 2.

As shown in FIG. 2, a semiconductor wafer bonding product 1000 is constituted from a stacked body in which a semiconductor wafer 101′, a spacer (spacer substrate) 104′ and a transparent substrate 102′ are stacked in this order. Namely, in the semiconductor wafer bonding product 1000, the semiconductor wafer 101′ and the transparent substrate 102′ are bonded together through the spacer 104′

The semiconductor wafer 101′ becomes the base substrate 101 of the semiconductor device 100 described above through a dicing step as described below.

Further, on one surface (upper surface) of the semiconductor wafer 101′, formed are a plurality of individual circuits each corresponding to the above mentioned individual circuit 103. In this regard, the plurality of individual circuits on the semiconductor wafer 101′ are not shown in FIG. 2.

As shown in FIG. 3, the spacer 104′ has a grid-like shape at a planar view thereof and is provided so as to surround each of the individual circuits on the semiconductor wafer 101′ (that is, the individual circuits 103 having the light receiving portions). Further, the spacer 104′ forms (defines) a plurality of air-gap portions 105 between the semiconductor wafer 101′ and the transparent substrate 102′. Namely, the plurality of air-gap portions 105 are arranged so as to correspond to the plurality of individual circuits at a planar view thereof.

This spacer 104′ is a member which becomes the spacer 104 of the semiconductor device 100 described above through the dicing step as described below.

The transparent substrate 102′ is bonded to the semiconductor substrate 101′ via the spacer 104′.

This transparent substrate 102′ is a member which becomes the transparent substrate 102 of the semiconductor device 100 described above through the dicing step as described below.

Such a semiconductor wafer bonding product 1000 is diced as described below so that a plurality of the semiconductor devices 100 can be obtained.

<Method of Manufacturing Semiconductor Device (Semiconductor Wafer Bonding Product)>

Next, description will be made on a preferred embodiment of a method of manufacturing a semiconductor device (semiconductor wafer bonding product) of the present invention. In this regard, hereinbelow, the description will be made on the method of manufacturing a semiconductor device as one example of a case of manufacturing the semiconductor device 100 and semiconductor wafer bonding product 1000 described above.

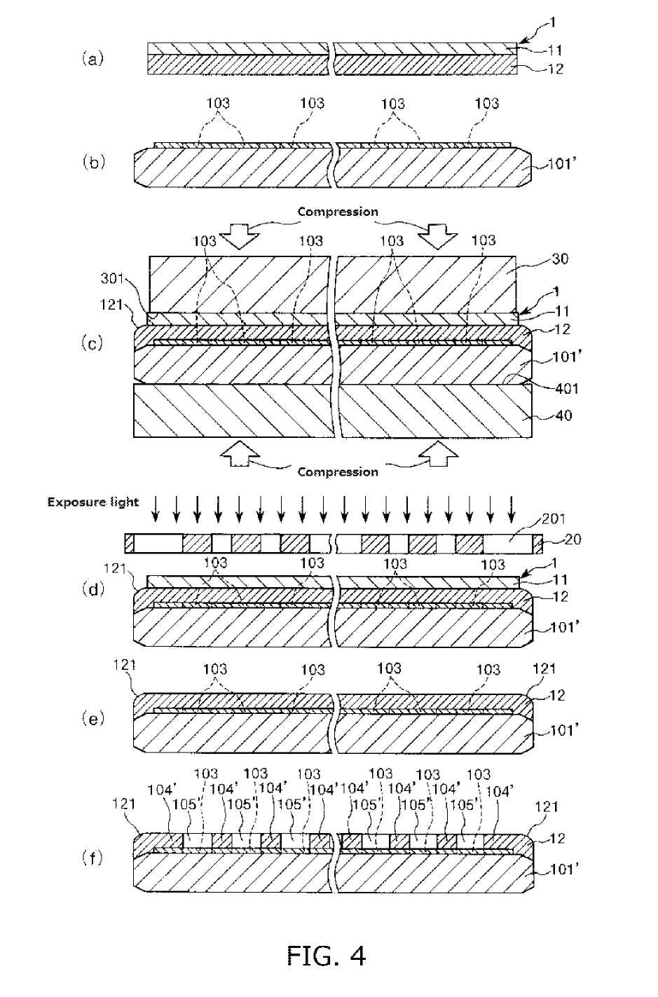

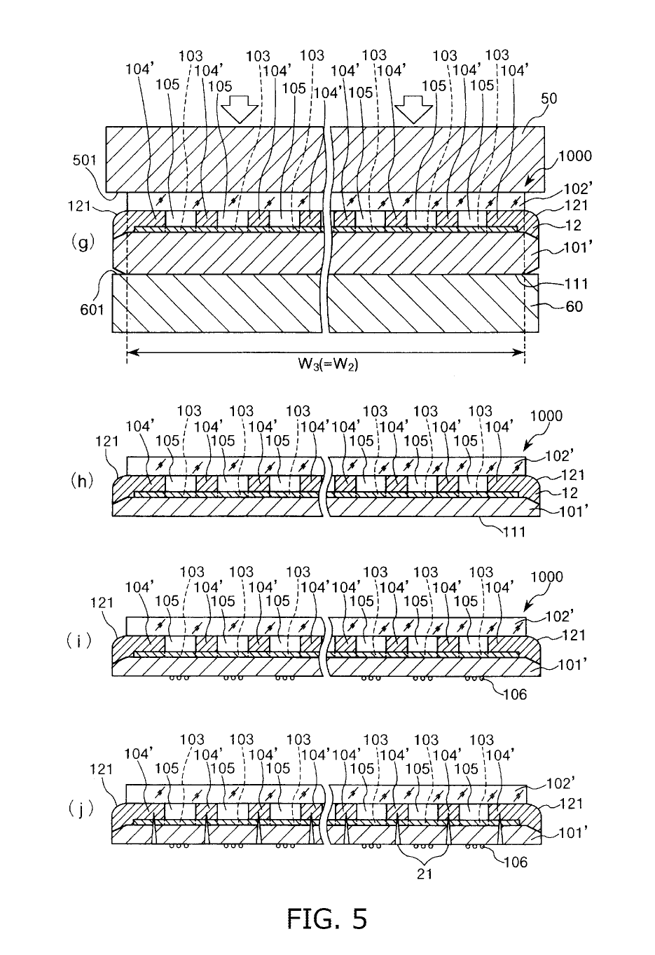

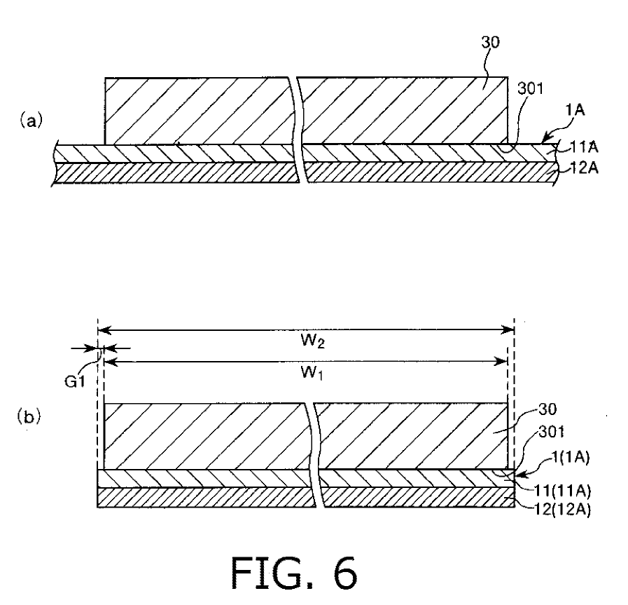

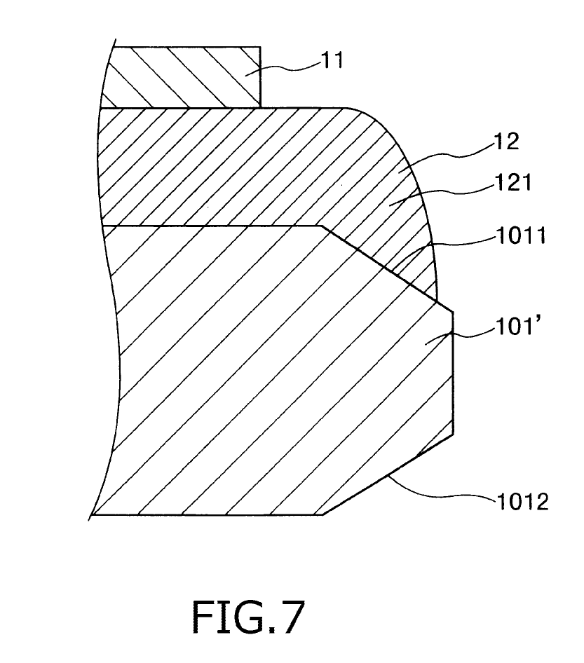

FIGS. 4 and 5 are process charts each showing one example of the method of manufacturing the semiconductor device shown in FIG. 1 (or the semiconductor wafer bonding product shown in FIG. 2), and FIGS. 6 and 7 are views each explaining the attaching process shown in FIG. 4(c).

The method of manufacturing the semiconductor device 100 includes [A] a step of producing the semiconductor wafer bonding product 1000 and [B] a step of dicing the semiconductor wafer bonding product 1000.

Here, a method of producing the semiconductor wafer bonding product 1000 (that is, the above step [A]) includes <<A1>> a step of attaching a spacer formation layer 12 to the semiconductor wafer 101′, <<A2>> a step of forming the spacer 104′ by selectively removing the spacer formation layer 12, <<A3>> a step of bonding the transparent substrate 102′ to a surface of the spacer 104′ opposite to the semiconductor wafer 101′ and <<A4>> a step of subjecting the lower surface of the semiconductor wafer 101′ to a predetermined processing or treatment.

Hereinbelow, each of the steps of the method of manufacturing the semiconductor device 100 will be described in detail one after another.

[A] Step of Producing Semiconductor Wafer Bonding Product 1000

<<A1>> Step of Attaching Spacer Formation Layer 12 to Semiconductor Wafer 101′

A1-1

First, as shown in FIG. 4(a), a spacer formation film 1 is prepared.

This spacer formation film 1 includes a support base 11 and the spacer formation layer 12 provided on the support base 11.

Such a spacer formation film 1 has been cut along an outer edge of a pressing surface 301 of a pressing member 30 of a machine for lamination (laminator) used in a process A1-3 (that is, a laminating process) described below.

When more specifically explained, as shown in FIG. 6(a), a support base 11A of a spacer formation film 1A before being cut is sucked (held) onto the pressing surface 301 of the pressing member 30.

And then, as shown in FIG. 6(b), in a state that the support base 11A has been sucked on the pressing surface 301, the spacer formation film 1A is cut along the outer edge of the pressing surface 301. In this way, the spacer formation film 1 is obtained.

By cutting the spacer formation film 1A along the outer edge of the pressing surface 301 in the state that the support base 11A has been sucked on the pressing surface 301 before the process A1-3 described below (that is, the laminating process) in such a way, the spacer formation layer 12 can have a necessary size for forming the spacer 104′.

Further, in the case where the spacer formation layer 12A and the support base 11A are cut in such a way, generally, the cutting is carried out by pushing a cutting tool or the like against the spacer formation layer 12A. Therefore, a size of the spacer formation film 1 obtained by being cut becomes slightly larger than that of the pressing surface 301. Namely, an outer edge of each of the spacer formation layer 12 and the support base 11 is located beyond the outer edge of the pressing surface 301.

Therefore, in the case where in a sectional view shown in FIG. 6, a width of the pressing surface 301 (that is, a diameter in the case of a circular pressing surface; and so forth) is defined as W₁ and a width of the support base 11 (spacer formation layer 12) is defined as W₂, W₁ and W₂ satisfy a relation of W₁<W₂.

Further, in the case where a distance between the outer edge of the pressing surface 301 and the outer edge of the support base 11 (spacer formation layer 12) is defined as G₁, G₁ satisfies a relation of G₁>0.

In this regard, the distance G₁ between the outer edge of the pressing surface 301 and the outer edge of the support base 11 is not limited to a specific value, but is preferably in the range of about 100 to 1,000 μm. This makes it possible to uniformly press an area of the spacer formation layer 12 which makes contact with the support base 11 by the pressing surface 301 during the attaching process described below.

Further, in this embodiment, the outer edge of the spacer formation layer 12 coincides with an outer edge of the semiconductor wafer 101′ in the process A1-3 described below (that is, the laminating process).

In this regard, it is to be noted that the spacer formation layer 12 may have such a size that the outer edge thereof is located beyond the outer edge of the semiconductor wafer 101′ in the process A1-3 described below (that is, the laminating process).

The support base 11 has a sheet-like shape and has a function for supporting the spacer formation layer 12.

This support base 11 has optical transparency. This makes it possible for the spacer formation layer to be exposed with an exposure light through the support base 11 in a state that the support base 11 is attached to the spacer formation layer 12 in an exposure treatment during the step <<A2>> described below.

A constituent material of such a support base 11 is not limited to a specific kind, as long as the support base 11 has the function of supporting the spacer formation layer 12 and the optical transparency as described above. Examples of the constituent material include polyethylene terephthalate (PET), polypropylene (PP), polyethylene (PE) and the like. Among them, it is preferable to use the polyethylene terephthalate (PET) as the constituent material of the support base 11 from the viewpoint that the support base 11 can exhibit both the optical transparency and rupture strength in excellent balance.

An average thickness of such a support base 11 is preferably in the range of 5 to 100 μm, and more preferably in the range of 15 to 50 μm. This makes it possible to appropriately handle the spacer formation film and to make a thickness of an area of the spacer formation layer, which makes contact with the support base, uniform.

Meanwhile, if the average thickness of the support base 11 is less than the above lower value, the support base 11 cannot exhibit the function of supporting the spacer formation layer 12. On the other hand, if the average thickness of the support base 11 exceeds the above upper value, it becomes difficult to handle the spacer formation film 1.

Further, exposure light transmission through the support base 11 in a thickness direction thereof is preferably in the range of 0.2 to 1, and more preferably in the range of 0.4 to 1. This makes it possible to reliably carry out the exposure treatment, in which the spacer formation layer 12 is exposed with the exposure light through the support base 11, during the exposure step described below.

On the other hand, the spacer formation layer 12 has a bonding property with respect to a surface of the semiconductor wafer 101′. This makes it possible to bond (attach) the spacer formation layer 12 and the semiconductor wafer 101′ together.

Further, the spacer formation layer 12 has a photo curable property (photosensitivity). This makes it possible to pattern the spacer formation layer 12 so as to have a predetermined shape by the exposure treatment and a developing treatment, to thereby form the spacer 104′ during the step <<A2>> described below.

Furthermore, the spacer formation layer 12 also has a thermal curable property. This makes it possible for the spacer formation layer 12 to develop a bonding property due to thermal curing thereof, even if it has been photo cured by the exposure treatment during the step <<A2>> described below. For this reason, the spacer formation layer 12 can bond the spacer 104′ and the transparent substrate 102′ together due to the thermal curing thereof during a step <<A3>> described below.

The spacer formation layer 12 is not limited to a specific one, as long as it can have the bonding property, the photo curable property and the thermal curable property as described above. It is preferred that the spacer formation layer 12 is constituted from a material containing an alkali soluble resin, a thermosetting resin and a photo initiator (hereinbelow, this material is referred to as “resin composition”).

Hereinbelow, description will be made on each of components of the resin composition in detail.

(Alkali Soluble Resin)

Examples of the alkali soluble resin include: a novolac resin such as a cresol-type novolac resin, a phenol-type novolac resin, a bisphenol A-type novolac resin, a bisphenol F-type novolac resin, a catechol-type novolac resin, a resorcinol-type novolac resin and a pyrogallol-type novolac resin; a phenol aralkyl resin; a hydroxystyrene resin; an acryl-based resin such as a methacrylic acid resin and a methacrylic acid ester resin; a cyclic olefin-based resin containing hydroxyl groups, carboxyl groups and the like; a polyamide-based resin; and the like. These alkali soluble resins may be used singly or in combination of two or more of them.

In this regard, concrete examples of the polyamide-based resin include: a resin containing at least one of a polybenzoxazole structure and a polyimide structure, and hydroxyl groups, carboxyl groups, ether groups or ester groups in a main chain or branch chains thereof; a resin containing a polybenzoxazole precursor structure; a resin containing a polyimide precursor structure; a resin containing a polyamide acid ester structure; and the like.

The spacer formation layer 12 containing such an alkali soluble resin can have an alkali developable property capable of reducing adverse effect on environment.

Among these alkali soluble resins, it is preferable to use an alkali soluble resin containing both alkali soluble groups, which contribute to the alkali developing, and double bonds.

Examples of the alkali soluble groups include a hydroxyl group, a carboxyl group and the like. The alkali soluble groups can also contribute to a thermal curing reaction in addition to the alkali developing. Further, since the alkali soluble resin contains the double bonds, it also can contribute to a photo curing reaction.

Examples of such a resin containing alkali soluble groups and double bonds include a curable resin which can be cured by both light and heat. Concrete examples of the curable resin include a thermosetting resin containing photo reaction groups such as an acryloyl group, a methacryloyl group and a vinyl group; a photo curable resin containing thermal reaction groups such as a phenolic hydroxyl group, an alcoholic hydroxyl group, a carboxyl group and an anhydride group; and the like.

By using the curable resin capable of being cured by both light and heat as the alkali soluble resin, it is possible to improve compatibility of the alkali soluble resin with respect to a thermosetting resin described below. As a result, strength of the spacer formation layer 12 after being cured, that is, the spacer 104′ can be improved.

In this regard, it is to be noted that the photo curable resin containing thermal reaction groups may further have other thermal reaction groups such as an epoxy group, an amino group and a cyanate group. Concrete examples of the photo curable resin having such a chemical structure include a (meth)acryl-modified phenol resin, an acryl acid polymer containing (meth)acryloyl groups, an (epoxy)acrylate containing carboxyl groups, and the like. Further, the photo curable resin may be a thermoplastic resin such as an acryl resin containing carboxyl groups.

Among the above resins each containing alkali soluble groups and double bonds (that is, the curable resins which can be cured by both light and heat), it is preferable to use the (meth)acryl-modified phenol resin.

By using the (meth)acryl-modified phenol resin, since the resin contains the alkali soluble groups, when the resin which has not reacted is removed during a developing treatment, an alkali solution having less adverse effect on environment can be used as a developer instead of an organic solvent which is normally used. Further, since the resin contains the double bonds, these double bonds contribute to the curing reaction. As a result, it is possible to improve heat resistance of the resin composition.

Furthermore, by using the (meth)acryl-modified phenol resin, it is possible to reliably reduce a degree of warp of the semiconductor wafer bonding product 1000. From the viewpoint of such a fact, it is also preferable to use the (meth)acryl-modified phenol resin.

Examples of the (meth)acryl-modified phenol resin include a (meth)acryloyl-modified bisphenol resin obtained by reacting hydroxyl groups contained in bisphenols with epoxy groups of compounds containing the epoxy groups and (meth)acryloyl groups.

Concretely, examples of such a (meth)acryloyl-modified bisphenol resin include a resin represented by the following chemical formula 1.

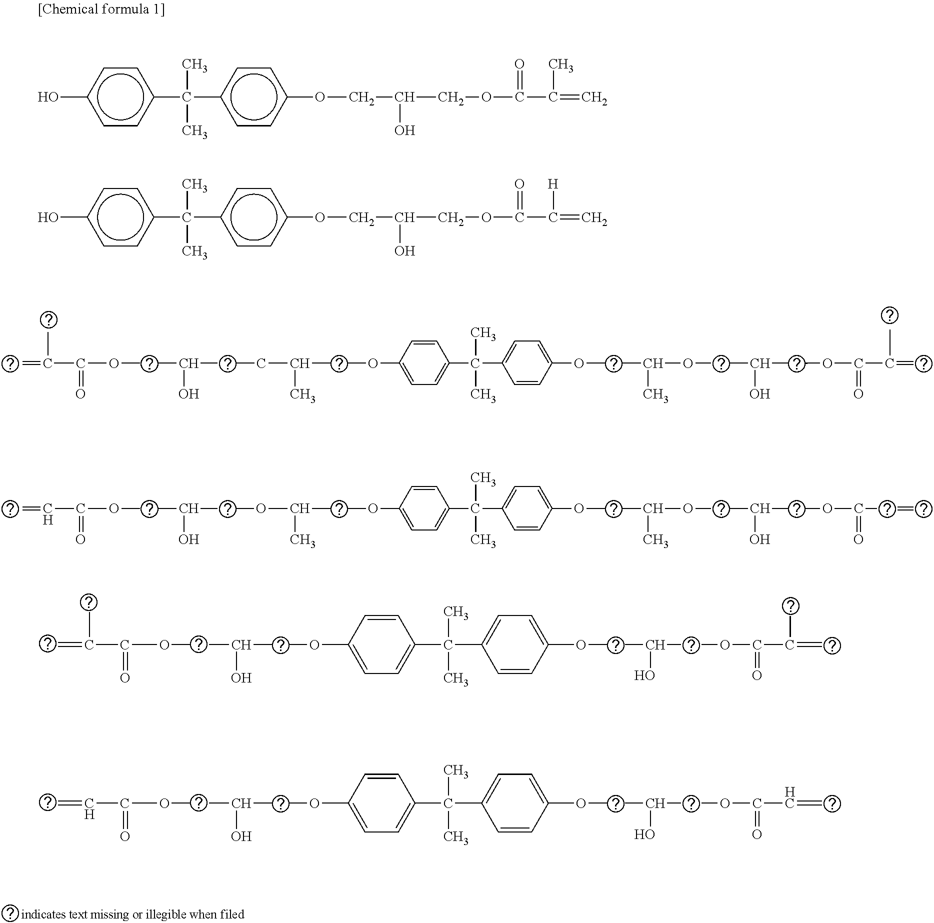

Further, as another (meth)acryloyl-modified bisphenol resin, exemplified is a compound introducing a dibasic acid into a molecular chain of a (meth)acryloyl-modified epoxy resin in which (meth) acryloyl groups are bonded to both ends of an epoxy resin, the compound obtained by bonding one of carboxyl groups of the dibasic acid to one hydroxyl group of the molecular chain of the (meth)acryloyl-modified epoxy resin via an ester bond. In this regard, it is to be noted that this compound has one or more repeating units of the epoxy resin and one or more dibasic acids introduced into the molecular chain.

Such a compound can be synthesized by reacting epoxy groups existing both ends of an epoxy resin obtained by polymerizing epichlorohydrin and polyalcohol with (meth)acrylic acid to obtain a (meth)acryloyl-modified epoxy resin in which acryloyl groups are introduced into both the ends of the epoxy resin, and then reacting hydroxyl groups of a molecular chain of the (meth)acryloyl-modified epoxy resin with an anhydride of a dibasic acid to form an ester bond together with one of carboxyl groups of the dibasic acid.

Here, in the case of using the thermosetting resin containing photo reaction groups, a modified ratio (substitutional ratio) of the photo reaction groups is not limited to a specific value, but is preferably in the range of about 20 to 80%, and more preferably about 30 to 70% with respect to total reaction groups of the resin containing alkali soluble groups and double bonds. If the modified ratio of the photo reaction groups falls within the above range, it is possible to provide a resin composition having an excellent developing property.

On the other hand, in the case of using the photo curable resin containing thermal reaction groups, a modified ratio (substitutional ratio) of the thermal reaction groups is not limited to a specific value, but is preferably in the range of about 20 to 80%, and more preferably in the range of about 30 to 70% with respect to total reaction groups of the resin containing alkali soluble groups and double bonds. If the modified ratio of the thermal reaction groups falls within the above range, it is possible to provide a resin composition having an excellent developing property.

Further, in the case where the resin having alkali soluble groups and double bonds is used as the alkali soluble resin, a weight-average molecular weight of the resin is not limited to a specific value, but is preferably 30,000 or less, and more preferably in the range of about 5,000 to 15,000. If the weight-average molecular weight falls within the above range, it is possible to further improve a film forming property of the resin composition in forming the spacer formation layer onto the support base 11.

Here, the weight-average molecular weight of the alkali soluble rein can be measured using, for example, a gel permeation chromatographic method (GPC). That is, according to such a method, the weight-average molecular weight can be calculated based on a calibration curve which has been, in advance, made using styrene standard substances. In this regard, it is to be noted that the measurement is carried out using tetrahydrofuran (THF) as a measurement solvent at a measurement temperature of 40° C.

Further, an amount of the alkali soluble resin contained in the resin composition is not limited to a specific value, but is preferably in the range of about 15 to 50 wt %, and more preferably in the range of about 20 to 40 wt % with respect to a total amount of the resin composition. In this regard, in the case where the resin composition contains a filler described below, the amount of the alkali soluble resin may be preferably in the range of about 10 to 80 wt %, and more preferably in the range of about 15 to 70 wt % with respect to resin components contained in the resin composition (total components excluding the filler).

If the amount of the alkali soluble resin falls within the above range, a mixing balance between the alkali soluble resin and the thermosetting resin described below can be optimized in the spacer formation layer 12. Therefore, it is possible to improve patterning resolution and development of the spacer formation layer 12 in the exposure treatment and the developing treatment during the step <<A2>> described below. Further, even after the spacer formation layer 12 has been subjected to the above treatments, the spacer formation layer 12, that is, the spacer 104′ can excellently maintain the bonding property thereof.

Meanwhile, if the amount of the alkali soluble resin is less than the above lower limit value, there is a case that an effect of improving compatibility with other components (e.g., the photo curable resin described below) contained in the resin composition is lowered. On the other hand, if the amount of the alkali soluble resin exceeds the upper limit value, there is a fear that the developing property of the resin composition or patterning resolution of the spacer 104′ formed by a photo lithography technique is lowered.

(Thermosetting Resin)

Examples of the thermosetting resin include: a novolac-type phenol resin such as a phenol novolac resin, a cresol novolac resin and a bisphenol A novolac resin; a phenol resin such as a resol phenol resin; a bisphenol-type epoxy resin such as a bisphenol A epoxy resin and a bisphenol F epoxy resin; a novlolac-type epoxy resin such as a novolac epoxy resin and a cresol novolac epoxy resin; an epoxy resin such as a biphenyl-type epoxy resin, a stilbene-type epoxy resin, a triphenol methane-type epoxy resin, an alkyl-modified triphenol methane-type epoxy resin, a triazine chemical structure-containing epoxy resin and a dicyclopentadiene-modified phenol-type epoxy resin; an urea resin; a resin having triazine rings such as a melamine resin; an unsaturated polyester resin; a bismaleimide resin; a polyurethane resin; a diallyl phthalate resin; a silicone resin; a resin having benzooxazine rings; a cyanate ester resin; an epoxy-modified-siloxane; and the like. These thermosetting resins may be used singly or in combination of two or more of them.

The spacer formation layer 12 containing such a thermosetting resin can exhibit a bonding property due to curing thereof, even after it has been exposed and developed. For this reason, after the spacer formation layer 12 has been bonded to the semiconductor wafer 101′, and exposed and developed, the transparent substrate 10 can be bonded to the spacer formation layer 12 (that is, the spacer 104′) by thermal bonding.

In this regard, in the case where the curable resin which can be cured by heat is used as the above alkali soluble resin, a resin other than the curable resin is selected as the thermosetting resin.

Further, among the thermosetting resins, it is preferable to use the epoxy resin. This makes it possible to improve heat resistance of the spacer formation layer 12 after being cured (that is, the spacer 104′) and adhesion of the transparent substrate 1 thereto.

Furthermore, in the case of using the epoxy resin as the thermosetting resin, it is preferred that an epoxy resin in a solid state at room temperature (in particular, bisphenol-type epoxy resin) and an epoxy resin in a liquid state at room temperature (in particular, silicone-modified epoxy resin in a liquid state at room temperature) are used in combination as the epoxy resin. This makes it possible to obtain a spacer formation layer 12 having excellent flexibility and resolution, while maintaining heat resistance thereof.

An amount of the thermosetting resin contained in the resin composition is not limited to a specific value, but preferably in the range of about 10 to 40 wt %, and more preferably in the range of about 15 to 35 wt % with respect to the total amount of the resin composition. If the amount of the thermosetting resin is less than the above lower limit value, there is a case that an effect of improving the heat resistance of the spacer formation layer 12 by the thermosetting resin is lowered. On the other hand, if the amount of the thermosetting resin exceeds the above upper limit value, there is a case that an effect of improving toughness of the spacer formation layer 12 by the thermosetting resin is lowered.

Further, in the case of using the above epoxy resin as the thermosetting resin, it is preferred that the thermosetting resin further contains the phenol novolac resin in addition to the epoxy resin. Addition of the phenol novolac resin makes it possible to improve the resolution of the spacer formation layer 12. Furthermore, in the case where the resin composition contains both the epoxy resin and the phenol novolac resin as the thermosetting resin, it is also possible to obtain an advantage that the thermal curable property of the epoxy resin can be further improved, to thereby make the strength of the spacer 104 to be formed higher.

(Photo Initiator)

Examples of the photo initiator include benzophenone, acetophenone, benzoin, benzoin isobutyl ether, benzoin methyl benzoic acid, benzoin benzoic acid, benzoin methyl ether, benzyl phenyl sulfide, benzyl, dibenzyl, diacetyl and the like.

The spacer formation layer 12 containing such a photo initiator can be more effectively patterned due to photo polymerization thereof.

An amount of the photo initiator contained in the resin composition is not limited to a specific value, but is preferably in the range of about 0.5 to 5 wt %, and more preferably in the range of about 0.8 to 3.0 wt % with respect to the total amount of the resin composition. If the amount of the photo initiator is less than the above lower limit value, there is a fear that an effect of starting the photo polymerization of the spacer formation layer 12 is lowered. On the other hand, if the amount of the photo initiator exceeds the above upper limit value, reactivity of the spacer formation layer 12 is extremely improved, and therefore there is a fear that storage stability or resolution thereof is lowered.

(Photo Polymerizable Resin)

It is preferred that the resin composition constituting the spacer formation layer 12 also contains a photo polymerizable resin in addition to the above components. This makes it possible to further improve a patterning property of the spacer formation layer 12 to be obtained.

In this regard, in the case where the curable resin which can be cured by light is used as the above alkali soluble resin, a resin other than the curable resin is selected as the photo polymerizable resin.

Examples of the photo polymerizable resin include: but are not limited to, an unsaturated polyester; an acryl-based compound such as an acryl-based monomer and an acryl-based oligomer each containing one or more acryloyl groups or one or more methacryloyl groups in one molecule thereof; a vinyl-based compound such as styrene; and the like. These photo polymerizable resins may be used alone or in combination of two or more of them.

Among them, an ultraviolet curable resin containing the acryl-based compound as a major component thereof is preferable. This is because a curing rate of the acryl-based compound is fast when being exposed with light, and therefore it is possible to appropriately pattern the resin with a relative small exposure amount.

Examples of the acryl-based compound include a monomer of an acrylic acid ester or methacrylic acid ester, and the like. Concretely, examples of the monomer include: a difunctional (meth)acrylate such as ethylene glycol di(meth)acrylate, 1,6-hexanediol di(meth)acrylate, glycerin di(meth)acrylate and 1,10-decanediol di(meth)acrylate; a trifunctional (meth)acrylate such as trimethylol propane tri(meth)acrylate and pentaerythritol tri(meth)acrylate; a tetrafunctional (meth)acrylate such as pentaerythritol tetra(meth)acrylate and ditrimethylol propane tetra(meth)acrylate; a hexafunctional (meth)acrylate such as dipentaerythritol hexa(meth)acrylate; and the like.

Among these acryl-based compounds, it is preferable to use an acryl-based polyfunctional monomer. This makes it possible for the spacer 104 to be obtained from the spacer formation layer 12 to exhibit excellent strength. As a result, a semiconductor device 100 provided with the spacer 104 can have a more superior shape keeping property.

In this regard, it is to be noted that, in the present specification, the acryl-based polyfunctional monomer means a monomer of a (meth)acrylic acid ester containing three or more acryloyl groups or (meth)acryloyl groups.

Further, among the acryl-based polyfunctional monomers, it is more preferable to use the trifunctional (meth)acrylate or the tetrafunctional (meth)acrylate. This makes it possible to exhibit the above effects more remarkably.

In this regard, in the case of using the acryl-based polyfunctional monomer, it is preferred that the photo polymerizable resin further contains an epoxy vinyl ester resin. In this case, since the acryl-based polyfunctional monomer is reacted with the epoxy vinyl ester resin by radical polymerization when exposing the spacer formation layer 12, it is possible to more effectively improve the strength of the spacer 104 to be formed. On the other hand, it is possible to improve solubility of the non-exposed region of the spacer formation layer 12 with the alkali developer when developing it, to thereby reduce residues after the development.

Examples of the epoxy vinyl ester resin include 2-hydroxyl-3-phenoxypropyl acrylate, EPOLIGHT 40E methacryl addition product, EPOLIGHT 70P acrylic acid addition product, EPOLIGHT 200P acrylic acid addition product, EPOLIGHT 80MF acrylic acid addition product, EPOLIGHT 3002 methacrylic acid addition product, EPOLIGHT 3002 acrylic acid addition product, EPOLIGHT 1600 acrylic acid addition product, bisphenol A diglycidyl ether methacrylic acid addition product, bisphenol A diglycidyl ether acrylic acid addition product, EPOLIGHT 200E acrylic acid addition product, EPOLIGHT 400E acrylic acid addition product, and the like.

In the case where the photo polymerizable resin contains the acryl-based polyfunctional monomer, an amount of the acryl-based polyfunctional monomer contained in the resin composition is not limited to a specific value, but is preferably in the range of about 1 to 50 wt %, and more preferably in the range of about to 25 wt %. This makes it possible to more effectively improve the strength of the spacer formation layer 12 after being exposed, that is, the spacer 104, and thus to more effectively improve the shape keeping property thereof when the transparent substrate 102 is bonded to the semiconductor wafer 101′.

Further, in the case where the photo polymerizable resin contains the epoxy vinyl ester resin in addition to the acryl-based polyfunctional monomer, an amount of the epoxy vinyl ester resin is not limited to a specific value, but is preferably in the range of about 3 to 30 wt %, and more preferably in the range of about 5 to 15 wt % with respect to the total amount of the resin composition. This makes it possible to more effectively reduce a residual ratio of residues attached to each surface of the semiconductor wafer 101′ and transparent substrate 102′ after the transparent substrate 102′ is bonded to the semiconductor wafer 101′.

Furthermore, it is preferred that the above photo polymerizable resin is of a liquid state at normal temperature. This makes it possible to further improve curing reactivity of the spacer formation layer by light irradiation (e.g., by ultraviolet ray irradiation). In addition, it is possible to easily mix the photo polymerizable resin with the other components (e.g., the alkali soluble resin). Examples of the photo polymerizable resin in the liquid form at the normal temperature include the above ultraviolet curable resin containing the acryl-based compound as the major component thereof, and the like.

In this regard, it is to be noted that a weight-average molecular weight of the photo polymerizable resin is not limited to a specific value, but is preferably 5,000 or less, and more preferably in the range of about 150 to 3,000. If the weight-average molecular weight falls within the above range, sensitivity of the spacer formation layer 12 becomes specifically higher. Further, the spacer formation layer 12 can also have superior resolution.

Here, the weight-average molecular weight of the photo polymerizable resin can be measured using the gel permeation chromatographic method (GPC), and is calculated in the same manner as described above.

(Inorganic Filler)

In this regard, it is to be noted that the resin composition constituting the spacer formation layer 12 may also contain an inorganic filler. This makes it possible to further improve the strength of the spacer 104 to be formed from the spacer formation layer 12.

However, in the case where an amount of the inorganic filler contained in the resin composition becomes too large, raised are problems such as adhesion of foreign substances derived from the inorganic filler onto the semiconductor wafer 101′ and occurrence of undercut after developing the spacer formation layer 12. For this reason, it is preferred that the amount of the inorganic filler contained in the resin composition is 9 wt % or less with respect to the total amount of the resin composition.

Further, in the case where the resin composition contains the acryl-based polyfunctional monomer as the photo polymerizable resin, since it is possible to sufficiently improve the strength of the spacer 104 to be formed from the spacer formation layer due to the addition of the acryl-based polyfunctional monomer, the addition of the inorganic filler to the resin composition can be omitted.

Examples of the inorganic filler include: a fibrous filler such as an alumina fiber and a glass fiber; a needle filler such as potassium titanate, wollastonite, aluminum borate, needle magnesium hydroxide and whisker; a platy filler such as talc, mica, sericite, a glass flake, scaly graphite and platy calcium carbonate; a globular (granular) filler such as calcium carbonate, silica, fused silica, baked clay and non-baked clay; a porous filler such as zeolite and silica gel; and the like. These inorganic fillers may be used alone or in combination of two or more of them. Among them, it is preferable to use the porous filler.

An average particle size of the inorganic filler is not limited to a specific value, but is preferably in the range of about 0.01 to 90 μm, and more preferably in the range of about 0.1 to 40 μm. If the average particle size exceeds the upper limit value, there is a fear that appearance and resolution of the spacer formation layer 12 are lowered. On the other hand, if the average particle size is less than the above lower limit value, there is a fear that the transparent substrate 102 cannot be reliably bonded to the spacer 104 even by the thermal bonding.

In this regard, it is to be noted that the average particle size is measured using, for example, a particle size distribution measurement apparatus of a laser diffraction type (“SALD-7000” produced by Shimadzu Corporation).

Further, in the case where the porous filler is used as the inorganic filler, an average hole size of the porous filler is preferably in the range of about 0.1 to 5 nm, and more preferably in the range of about 0.3 to 1 nm.

The resin composition constituting the spacer formation layer 12 also can contain an additive agent such as a plastic resin, a leveling agent, a defoaming agent or a coupling agent in addition to the above components insofar as the purpose of the present invention is not spoiled.

By constituting the spacer formation layer from the resin composition described above, it is possible to more appropriately adjust visible light transmission through the spacer formation layer 12, to thereby more effectively prevent the exposure from becoming insufficiency during the exposing step. As a result, it is possible to provide a semiconductor device 100 having higher reliability.

An average thickness of such a spacer formation layer 12 is not limited to a specific value, but is preferably in the range of 5 to 350 μm. This makes it possible to define an air-gap portion 105 having a size to be required by the spacer 104. Further, this also makes it possible to reliably carry out the exposure treatment in which the spacer formation layer 12 is irradiated with the exposure light through the support base 11 and the developing treatment in which the spacer formation layer 12 from which the support base 11 is removed is developed after the exposure treatment.

Meanwhile, if the average thickness of the spacer formation layer 12 is less than the above lower value, the spacer 104 cannot define an air-gap portion 105 having a size to be required. On the other hand, if the average thickness of the spacer formation layer exceeds the above upper value, it is difficult to form a spacer 104 having an uniform thickness. Further, it is difficult to reliably carry out the exposure treatment in which the spacer formation layer is irradiated with the exposure light through the support base 11. Furthermore, if the average thickness of the spacer formation layer 12 exceeds the above upper value, it is difficult to reliably carry out the developing treatment.

Further, exposure light transmission through the spacer formation layer 12 in a thickness direction thereof is not limited to a specific value, but is preferably in the range of 0.1 to 0.9. This makes it possible to reliably carry out the exposure treatment in which the spacer formation layer 12 is irradiated with the exposure light through the support base 11 during the exposure step described below.

In this regard, in the present specification, the exposure light transmission through each of the support base 11 and the spacer formation layer 12 in the thickness direction thereof means transmission of a peak wavelength (e.g., 365 nm) of the exposure light through each of the support base 11 and the spacer formation layer 12 in the thickness direction thereof. Further, the light transmission through each of the support base 11 and the spacer formation layer 12 in the thickness direction thereof can be measured using, for example, a transmission measuring apparatus (“UV-160A” produced by Shimadzu Corporation).

Further, an average thickness of the spacer formation film 1 is not limited to a specific value, but is preferably in the range of 5 to 350 μm. Meanwhile, if such an average thickness is less than 5 μm, there is a case that the support base 11 cannot exhibit the function of supporting the spacer formation layer 12 or the spacer 104 cannot form an air-gap portion 105 having a necessary size. On the other hand, if the average thickness exceeds 350 μm, it becomes difficult to handle the spacer formation film 1.

A1-2

On the other hand, as shown in FIG. 4(b), the plurality of individual circuits 103 are formed onto the one surface of the semiconductor wafer 101′. Specifically, the plurality of light receiving elements and the plurality of microlens arrays are formed onto the one surface of the semiconductor wafer 101′ in this order.

A1-3

Next, as shown in FIG. 4(c), the spacer formation layer 12 of the spacer formation film 1 is attached to the one surface of the semiconductor wafer 101′ from a side of the one surface thereof (that is, laminating processing is carried out).

When more specifically explained, in the state that the support base 11 is sucked onto the pressing surface 301 of the pressing member 30 as described above (see FIG. 6(b)), the spacer formation film 1 is moved above the surface of the semiconductor wafer 101′ on which the individual circuits 103 having the light receiving portions are formed.

On the other hand, a surface of the semiconductor wafer 101′ opposite to the individual circuits 103 having the light receiving portions is placed onto a pressing surface 401 of a pressing member 40.

In this state, the pressing member 30 and the pressing member 40 are moved in a direction where the pressing surface 301 and the pressing surface 401 come closer to each other. In this way, the support base 11 is pressed (compressed) toward the spacer formation layer 12 by the pressing surface 301.

By pressing the support base 11 toward the spacer formation layer 12 by the pressing surface 301 in this way, the spacer formation layer 12 can uniformly make contact with the semiconductor wafer 101′, to thereby be attached onto the semiconductor wafer 101′.

In the case where the spacer formation layer is attached on the semiconductor wafer 101′ as described above, generally, the outer edge of the spacer formation layer 12 is extruded beyond the outer edge of the support base 11. An extruded portion 121 rises upward with respect to another portion (that is, a portion of the spacer formation layer 12 making contact with the support base 11), to thereby become thick.

At this time, the spacer formation layer 12 is attached to the semiconductor wafer 101′ so that the outer edge of the spacer formation layer 12 coincides with the outer edge of the semiconductor wafer 101′.

Further, as shown in FIG. 7, upper and lower outer (peripheral) portions of the semiconductor wafer 101′ are chamfered. Specifically, a chamfered portion 1011 is formed at an upper side of the outer edge of the semiconductor wafer 101′ and a chamfered portion 1012 is formed at a lower side of the outer edge of the semiconductor wafer 101′.

By attaching the spacer formation layer 12 to the semiconductor wafer 101′ so that the outer edge of the spacer formation layer 12 coincides (or substantially coincides) with the outer edge of the semiconductor wafer 101′, the outer edge of the spacer formation layer 12 is located on or near the chamfered portion (specifically, the chamfered portion 1011). This makes it possible to prevent or suppress the portion 121 of the spacer formation layer 12 which is extruded beyond the outer edge of the support base 11 from becoming thick due to rising thereof.

In this embodiment, as shown in FIG. 7, by chamfering the upper and lower outer portions of the semiconductor wafer 101′ so as to have angular shapes, respectively, the chamfered portions 1011, 1012 are formed.

In this regard, a shape of each of the chamfered portions 1011, 1012 is not limited to the above one, but may be any shape to be formed by a well-known chamfering processing. Even in such a case, it is possible to obtain the effect of preventing or suppressing the above mentioned extruded portion 121 from rising.

For example, the chamfered portions 1011, 1012 may be formed by chamfering the upper and lower outer portions of the semiconductor wafer 101′ so as to have round shapes, respectively. Further, the upper outer portion of the semiconductor wafer 101′ (that is, a portion of the outer edge of the semiconductor wafer 101′ located at a side of a surface thereof on which the spacer formation layer 12 is to be attached) has only to be chamfered, for example, the chamfered portion 1012 may be omitted.

Therefore, the spacer 104 and the transparent substrate 102′ can be uniformly bonded together without forming a space therebetween during the step <<A3>> described below (that is, a bonding step).

<<A2>> Step of forming spacer 104′ by selectively removing spacer formation layer 12

A2-1

Next, as shown in FIG. 4(d), the exposure treatment is carried out by irradiating the spacer formation layer 12 with an exposure light (ultraviolet ray) (that is, this process is referred to as an exposure process).

At this time, as shown in FIG. 4(d), the spacer formation layer 12 is irradiated with the exposure light through a mask 20 having a light passing portion 201 with a top view shape corresponding to a top view shape of the spacer 104′.

The light passing portion 201 has light transparency. Therefore, the spacer formation layer 12 is irradiated with the exposure light passed through the light passing portion 201. In this way, the spacer formation layer 12 is selectively exposed so that a region thereof which is irradiated with the exposure light is photo-cured.

Further, as shown in FIG. 4(d), the exposure treatment with respect to the spacer formation layer 12 is carried out in a state that the support base 11 is attached to the spacer formation layer 12. Therefore, the spacer formation layer 12 is irradiated with the exposure light passed through the support base 11.

For this reason, the support base 11 can function as a protective layer of the spacer formation layer 12 during the exposure treatment, which makes it possible to prevent adhesion of foreign substances such as dust to the surface of the spacer formation layer effectively. Further, even in the case where the foreign substances adhere to the support base 11, they can be easily removed.

Furthermore, even when the mask 20 is placed as described above, it is possible to prevent the mask 20 from adhering to the spacer formation layer 12, while making a distance between the mask 20 and the spacer formation layer 12 smaller. As a result, it is possible to prevent an image to be formed from the exposure light, with which the spacer formation layer 12 is irradiated, from becoming dim.

In this case, a border between an exposed region and a non-exposed region can become sharp (clear). As a result, it is possible to form the spacer 104′ at sufficient dimensional accuracy, to thereby obtain each air-gap portion 105 so as to have a close designed shape. This makes it possible to improve reliability of a semiconductor device 100.

In this regard, when the mask 20 is placed, by setting an alignment mark provided on the semiconductor wafer 101′ and an alignment mark provided on the mask 20 together, the mask 20 can be aligned with regard to the semiconductor wafer 101′.

A distance between the support base 11 and the mask 20 is preferably in the range of 0 to 100 μm, and more preferably in the range of 0 to 50 μm. This makes it possible to more clearly form the image to be formed from the exposure light, with which the spacer formation layer 12 is irradiated through the mask 20, to thereby form the spacer 104 at sufficient dimensional accuracy.

Especially, it is preferred that the exposure treatment is carried out in the state that the mask 20 makes contact with the support base 11. This makes it possible to keep a distance between the spacer formation layer 12 and the mask 20 stably and constantly in a whole region thereof. As a result, it is possible to uniformly expose a region of the spacer formation layer 12 to be exposed, to thereby more effectively form a spacer 104′ having excellent dimensional accuracy.

In the case where the exposure is carried out in such a state that the mask 20 makes contact with the support base 11, by appropriately selecting the thickness of the support base 11, it is possible to set the distance between the support base 11 and the mask freely and reliably. Further, by adjusting the thickness of the support base 11 to a small size, it is possible to make the distance between the spacer formation layer 12 and the mask 20 smaller. This makes it possible to prevent the image to be formed from the exposure light, with which the spacer formation layer 12 is irradiated, from becoming dim.

In this regard, the exposure of the spacer formation layer 12 may be carried out so that the mask 20 does not make contact with the support base 11 using a projection exposure apparatus or a reduced projection exposure apparatus. In this case, the exposure of the spacer formation layer 12 also may be carried out after the support base 11 has been removed.

It is preferred that the light, with which the spacer formation layer 12 is irradiated, is a chemical ray (ultraviolet ray). A wavelength thereof is preferably in the range of about 150 to 700 nm, and more preferably in the range of about 170 to 450 nm.

Further, integrated dose of the irradiated light is preferably in the range of about 200 to 3,000 J/cm², and more preferably in the range of about 300 to 2,500 J/cm².

In this regard, it is to be noted that after the exposure, the spacer formation layer 12 may be subjected to a baking (heating) treatment at a temperature of about 40 to 80° C. (this process is referred to as a post exposure baking process (PEB process)).

This makes it possible to more firmly bond a region of the spacer formation layer 12 to be brought into the spacer 104 to the individual circuit 103 having the light receiving portion. Further, this also makes it possible to reduce residual stress remaining in the spacer formation layer 12.

During such a heat treatment, a heat temperature of the spacer formation layer 12 is preferably in the range of about 20 to 120° C., and more preferably in the range of about 30 to 100° C.

Further, a heat time of the spacer formation layer 12 is preferably in the range of about 1 to 10 minutes, and more preferably in the range of about 2 to 7 minutes.

A2-2

Next, as shown in FIG. 4(e), the support base 11 is removed (this process is referred to as a support base removing process). Namely, the support base 11 is peeled off from the spacer formation layer 12.

By removing the support base 11 before the development after the exposure has been carried out in such a way, the spacer formation layer 12 can be patterned while preventing the foreign substances such as the dust from adhering the spacer formation layer 12 during the exposure described above.

A2-3

Next, as shown in FIG. 4(f), the non-cured region of the spacer formation layer 12 is removed using a developer (this process is referred to as a developing process). By doing so, the photo-cured region of the spacer formation layer 12 is remained, to thereby form the spacer 104′ and the air-gap portions 105′.

At this time, in the case where the spacer formation layer 12 contains the above mentioned alkali soluble resin, an alkali aqueous solution can be used as the developer.

<<A3>> Step of bonding transparent substrate 102′ to surface of spacer 104′ opposite to semiconductor wafer 101′

Next, as shown in FIG. 5(g), the transparent substrate 102′ is bonded to an upper surface of the formed spacer 104′ (this step is referred to as a bonding step). In this way, it is possible to obtain a semiconductor wafer bonding product 1000 (semiconductor wafer bonding product of the present invention) in which the semiconductor wafer 101′ and the transparent substrate 102′ are bonded together through the spacer 104′.

The bonding of the transparent substrate 102′ to the spacer 104′ can be carried out, for example, by attaching the transparent substrate 102′ to the upper surface of the formed spacer 104′, and then being subjected to thermal bonding.

When more specifically explained, as shown in FIG. 5(g), a pressing surface 501 of a pressing member 50 provided above the transparent substrate 102′ and a pressing surface 601 of a pressing member 60 provided below the semiconductor wafer 101′ come near together so that the transparent substrate 102′ and the semiconductor wafer 101′ are pressed (compressed).

At this time, by heating them, the transparent substrate 102′ is bonded to the spacer formation layer 12 (that is, the spacer 104′).

Especially, the transparent substrate 102′ is bonded to a region of the spacer 104′ where the removed support base 11 was provided so that the transparent substrate 102′ is included within the region. Namely, the transparent substrate 102′ is bonded to a region of the spacer 104′ having an uniform thickness (flat surface) with keeping away from a convex portion (rib) 121 formed along the outer edge of the spacer 104′.

For this reason, the spacer 104′ and the transparent substrate 102′ can be uniformly bonded together without forming a space therebetween.

As a result, it is possible to prevent bonding defects in the outer edge of the semiconductor wafer. This makes it possible to improve a yield of semiconductor devices 100 obtained by dicing the semiconductor wafer bonding product 1000.

In this embodiment, a width (diameter) W₃ of the transparent substrate 102′ is equal to the width W₂ of the above mentioned support base 11. Further, the transparent substrate 102′ is placed onto the spacer 104′ so that the outer edge of the transparent substrate 102′ coincides with the outer edge of the region of the spacer 104′ where the removed support base 11 was provided.

As described above, the spacer formation layer 12 is attached to the semiconductor wafer 101′ so that the outer edge of the spacer formation layer 12 coincides (or substantially coincides) with the outer edge of the semiconductor wafer 101′. By doing so, it is possible to prevent or suppress the portion 121 of the spacer formation layer 12, which is extruded beyond the outer edge of the support base 11, from rising due to the existence of the chamfered portion 1011 formed by chamfering the outer portion of the semiconductor wafer 101′, so that the portion 121 hardly becomes thick (see FIG. 7).

This makes it possible to more reliably prevent a space from being formed between the spacer 104 and the transparent substrate 102′ when being bonded together.

In this regard, it is to be noted that the width (diameter) W₃ of the transparent substrate 102′ can be set to a value smaller than the width W₂ of the support base 11.

The thermal bonding is preferably carried out within a temperature range of 80 to 180° C. This makes it possible for the spacer 104′ and the transparent substrate 102′ to be bonded together by the thermal bonding while suppressing the applied pressure during the thermal bonding. Therefore, involuntary deformation of the spacer 104 to be formed can be prevented, to thereby improve dimensional accuracy thereof.

<<A4>> Step of subjecting lower surface of semiconductor wafer 101′ to predetermined processing or treatment

A4-1

Next, as shown in FIG. 5(h), ground is a surface (lower surface) 111 of the semiconductor wafer 101′ opposite to the transparent substrate 102′ (this process is referred to as a back grinding process).

This surface 111 of the semiconductor wafer 101′ can be ground using, for example, a grinding machine (grinder).

By grinding such a surface 111, a thickness of the semiconductor wafer 101′ is generally set to about 100 to 600 μm depending on an electronic device in which the semiconductor device 100 is used. In the case where the semiconductor device 100 is used in an electronic device having a smaller size, the thickness of the semiconductor wafer 101′ is set to about 50 μm.

A4-2

Next, as shown in FIG. 5(i), the solder bumps 106 are formed onto the surface 111 of the semiconductor wafer 101′.

At this time, a circuit (wiring) is also formed onto the surface 111 of the semiconductor wafer 101′ in addition to the solder bumps 106, but is not shown in the drawings.

[B] Step of Dicing Semiconductor Wafer Bonding Product 1000

Next, the semiconductor wafer bonding product 1000 is diced, to thereby obtain the plurality of semiconductor devices 100 (this step is referred to as a dicing step).

At this time, the semiconductor wafer bonding product 1000 is diced so as to correspond to each individual circuit formed on the semiconductor wafer 101′, that is, each air-gap portion 105.

For example, the dicing of the semiconductor wafer bonding product 1000 is carried out by, as shown in FIG. 5(j), forming grooves 21 from a side of the semiconductor wafer 101′ using a dicing saw along a grid of the spacer 104′, and then also forming grooves from a side of the transparent substrate 102′ using the dicing saw so as to correspond to the grooves 21.

Through the above steps, the semiconductor device 100 can be manufactured.

In this way, by dicing the semiconductor wafer bonding product 1000 to thereby obtain the plurality of semiconductor devices 100 at the same time, it is possible to mass-produce the semiconductor devices 100, and thus to improve productive efficiency thereof.

In this regard, for example, by mounting the semiconductor device 100 on a substrate provided with a circuit (patterned wiring), the circuit formed on the substrate is electrically connected to the circuit formed on the lower surface of the base substrate 101 via the solder bumps 106.

Further, the semiconductor device 100 mounted on the support substrate as described above can be widely used in electronics such as a cellular telephone, a digital camera, a video camera and a miniature camera.

### Second Embodiment

Next, description will be made on a second embodiment of the present invention.

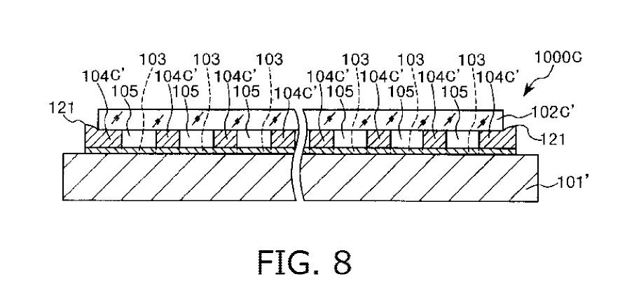

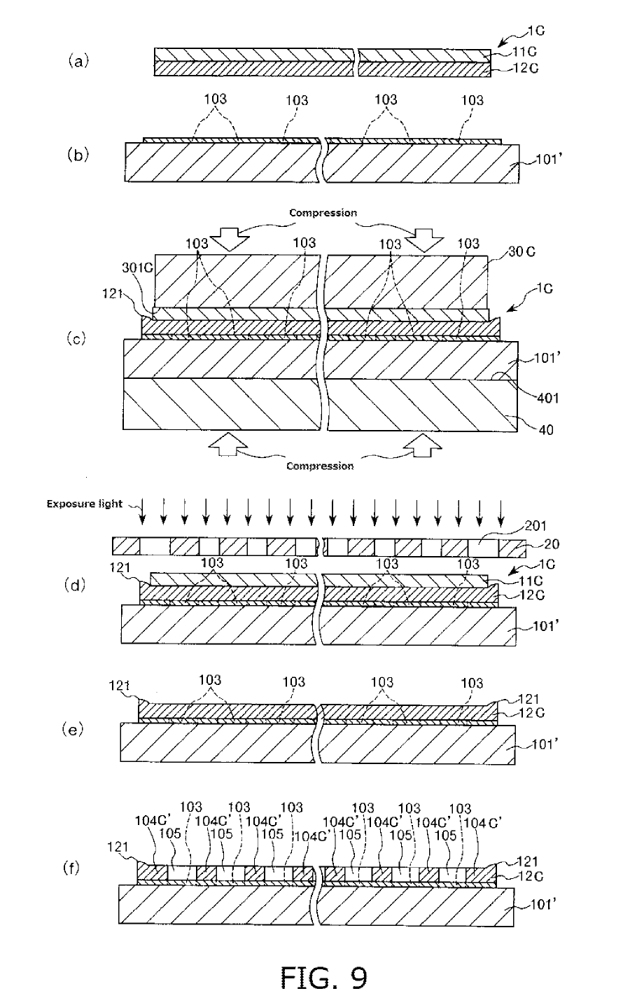

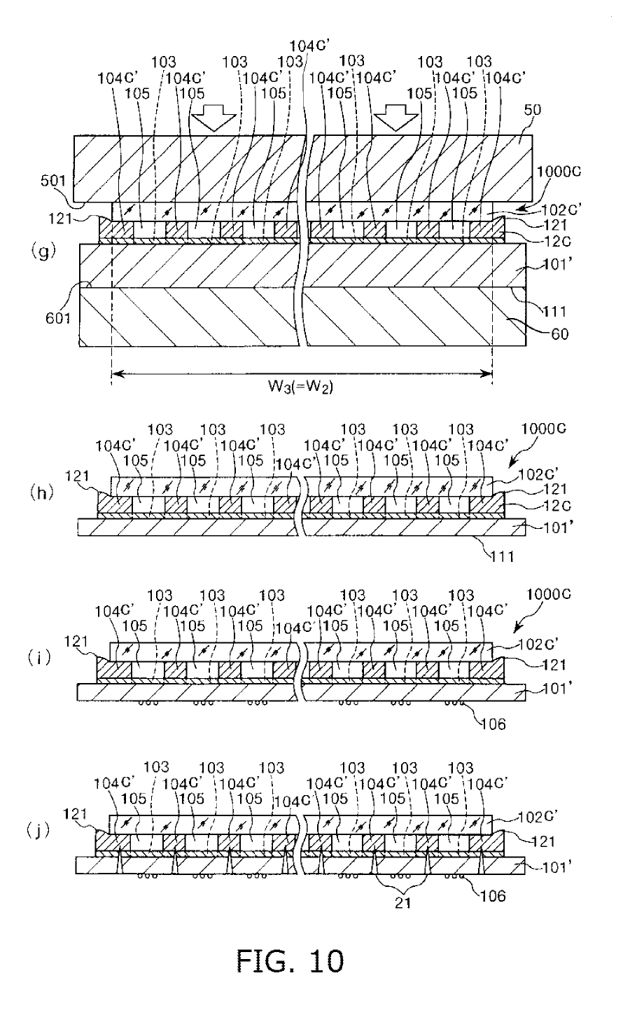

FIG. 8 is a longitudinal sectional view showing a semiconductor wafer bonding product according to an embodiment of the present invention. FIGS. 9 and 10 are process charts each showing one example of the method of manufacturing the semiconductor device shown in FIG. 8.

Hereinbelow, the semiconductor wafer bonding product and the method of manufacturing the same according to the second embodiment will be described with emphasis placed on points differing from the above mentioned embodiment. No description will be made on the same points. In this regard, it is to be noted that the same reference numbers are applied to the same components shown in FIGS. 8 to 10 as those of the above mentioned embodiment.

The second embodiment is almost the same as the first embodiment except that sizes of the spacer formation film, the pressing member and the transparent substrate are different from each other.

<Semiconductor Wafer Bonding Product>

As shown in FIG. 8, a semiconductor wafer bonding product 1000 is constituted from a stacked body in which a semiconductor wafer 101′, a spacer 104C′ and a transparent substrate 102C′ are stacked in this order. Namely, in the semiconductor wafer bonding product 1000C, the semiconductor wafer 101′ and the transparent substrate 102C′ are bonded together through the spacer 104C′

The spacer 104C′ has a grid-like shape at a planar view thereof and is provided so as to surround each of the individual circuits (that is, the individual circuits 103 having the light receiving portions) on the semiconductor wafer 101′. Further, the spacer 104C′ forms (defines) a plurality of air-gap portions 105 between the semiconductor wafer 101′ and the transparent substrate 102C′. Namely, the plurality of air-gap portions 105 are arranged so as to correspond to the plurality of individual circuits described above at a planar view thereof.

This spacer 104C′ is a member which becomes the spacer 104 of the semiconductor device 100 described above through a dicing step as described below.

The transparent substrate 102C′ is bonded to the semiconductor substrate 101′ via the spacer 104C′.

This transparent substrate 102C′ is a member which becomes the transparent substrate 102 of the semiconductor device 100 described above through the dicing step as described below.

Such a semiconductor wafer bonding product 1000C is diced as described below so that a plurality of the semiconductor devices 100 can be obtained.

<Method of Manufacturing Semiconductor Device (Semiconductor Wafer Bonding Product)>

Next, description will be made on the method of manufacturing a semiconductor wafer bonding product as one example of a case of manufacturing the semiconductor wafer bonding product 1000C.

The method of manufacturing the semiconductor wafer bonding product 1000C includes <<C1>> a step of attaching a spacer formation layer 12C to the semiconductor wafer 101′, <<C2>> a step of forming the spacer 104C′ by selectively removing the spacer formation layer 12C, <<C3>> a step of bonding the transparent substrate 102C′ to a surface of the spacer 104C′ opposite to the semiconductor wafer 101′ and <<C4>> a step of subjecting a lower surface of the semiconductor wafer 101′ to a predetermined processing or treatment.

<<C1>> Step of Attaching Spacer Formation Layer 12C to semiconductor wafer 101′

C1-1

First, as shown in FIG. 9(a), a spacer formation film 1C is prepared.

This spacer formation film 1C includes a support base 11C and the spacer formation layer 12C provided on the support base 11C.

Such a spacer formation film 1C has been cut along an outer edge of a pressing surface 301C of a pressing member 30C of a machine for lamination (laminator) used in a process C1-3 (that is, a laminating process) described below. The spacer formation film 1C is the same as the above mentioned spacer formation film 1 except that sizes thereof are deferent from each other.

Further, the spacer formation layer 12C has such a size that an outer edge thereof is located within an outer edge of the semiconductor wafer 101′ in the process C1-3 described below (that is, the laminating process).

C1-2

On the other hand, as shown in FIG. 9(b), the plurality of individual circuits 103 are formed onto one surface of the semiconductor wafer 101′. This process can be carried out in the same manner as the above mentioned process A1-2 of the first embodiment.

C1-3

Next, as shown in FIG. 9(c), the spacer formation layer 12C of the spacer formation film 1C is attached to the one surface of the semiconductor wafer 101′ from a side of the one surface thereof (that is, laminating processing is carried out). This process can be carried out in the same manner as the above mentioned process A1-3 of the first embodiment.

At this time, in this process, the spacer formation layer 12C is attached to the semiconductor wafer 101′ so that the outer edge of the spacer formation layer 12C is located within the outer edge of the semiconductor wafer 101′.

<<C2>> Step of Forming Spacer 104′ by Selectively Removing Spacer Formation Layer 12C

C2-1

Next, as shown in FIG. 9(d), the exposure treatment is carried out by irradiating the spacer formation layer 12C with an exposure light (ultraviolet ray) (that is, this process is referred to as an exposure process). This process can be carried out in the same manner as the above mentioned process A2-1 of the first embodiment.

C2-2

Next, as shown in FIG. 9(e), the support base 11C is removed (this process is referred to as a support base removing process). Namely, the support base 11C is peeled off from the spacer formation layer 12C. This process can be carried out in the same manner as the above mentioned process A2-2 of the first embodiment.

C2-3

Next, as shown in FIG. 9(f), a non-cured region of the spacer formation layer 12 is removed using a developer (this process is referred to as a developing process). By doing so, a photo-cured region of the spacer formation layer 12C is remained, to thereby form the spacer 104C′ and spaces 105′ to be brought into the air-gap portions. This process can be carried out in the same manner as the above mentioned process A2-3 of the first embodiment.

<<C3>> Step of Bonding Transparent Substrate 102C′ to Surface of Spacer 104C′ Opposite to Semiconductor Wafer 101′

Next, as shown in FIG. 10(g), the transparent substrate 102C′ is bonded to an upper surface of the formed spacer 104C′ (this step is referred to as a bonding step). In this way, it is possible to obtain a semiconductor wafer bonding product 1000C (semiconductor wafer bonding product of the present invention) in which the semiconductor wafer 101′ and the transparent substrate 102C′ are bonded together through the spacer 104C′. This step can be carried out in the same manner as the above mentioned step <<A3>> of the first embodiment.

<<C4>> Step of Subjecting Lower Surface of Semiconductor Wafer 101′ to Predetermined Processing or Treatment

C4-1

Next, as shown in FIG. 10(h), ground is a surface (lower surface) 111 of the semiconductor wafer 101′ opposite to the transparent substrate 102C′ (this process is referred to as a back grinding process). This process can be carried out in the same manner as the above mentioned process A4-1 of the first embodiment.

C4-2

Next, as shown in FIG. 10(i), solder bumps 106 are formed onto the surface 111 of the semiconductor wafer 101′. This process can be carried out in the same manner as the above mentioned process A4-2 of the first embodiment.

Thereafter, the semiconductor wafer bonding product 1000C is diced, to thereby obtain the plurality of semiconductor devices 100 (this step is referred to as a dicing step). This step can be carried out in the same manner as the above mentioned step [B] of the first embodiment.

Through the above steps, the semiconductor device 100 can be manufactured.

While the present invention has been described hereinabove with reference to the preferred embodiments, the present invention is not limited thereto.

For example, in the method of manufacturing a semiconductor wafer bonding product according to the present invention, one or more steps (processes) may be added for arbitrary purposes. For example, between the laminating process and the exposing process, a post lamination baking process (PLB process), in which the spacer formation layer is subjected to a baking (heating) treatment, may be provided.

Further, in the description of the above embodiments, the exposure is carried out just once, but may be, for example, more than once.

Furthermore, each component constituting the semiconductor wafer bonding product and the semiconductor device is substituted for an arbitrary component having the same function as it, or arbitrary structures also may be added thereto.

### INDUSTRIAL APPLICABILITY

A method of manufacturing a semiconductor wafer bonding product according to the present invention includes: a step of preparing a spacer formation film including a support base having a sheet-like shape and a spacer formation layer provided on the support base and having photosensitivity; a step of attaching the spacer formation layer to a semiconductor wafer having one surface from a side of the one surface; a step of forming a spacer by subjecting the spacer formation layer to exposure and development to be patterned and removing the support base; and a step of bonding a transparent substrate to a region of the spacer where the removed support base was provided so that transparent substrate is included within the region. This makes it possible to manufacture a semiconductor wafer bonding product in which the semiconductor wafer and the transparent substrate are bonded together through the spacer uniformly and reliably. Such a present invention provides industrial applicability.

What is claimed is:

1. A method of manufacturing a semiconductor wafer bonding product, comprising:
a step of preparing a spacer formation film including a support base having a sheet-like shape and a spacer formation layer provided on the support base and having photosensitivity;
a step of attaching the spacer formation layer to a semiconductor wafer having one surface from a side of the one surface;
a step of forming a spacer by subjecting the spacer formation layer to exposure and development to be patterned and removing the support base; and
a step of bonding a transparent substrate to a region of the spacer where the removed support base was provided so that transparent substrate is included within the region.

2. The method as claimed in claim 1, wherein in the step of attaching the spacer formation layer to the semiconductor wafer, the spacer formation layer is attached onto the semiconductor wafer so that an outer edge of the spacer formation layer is located beyond an outer edge of the support base.

3. The method as claimed in claim 2 further comprising: a step of sucking the support base to a pressing surface of a pressing member to bring it into a sucked state and cutting the spacer formation film along an outer edge of the pressing surface in the sucked state, before the step of attaching the spacer formation layer to the semiconductor wafer.

4. The method as claimed in claim 3, wherein in the step of attaching the spacer formation layer to the semiconductor wafer, the support base is pressed toward the spacer formation layer by the pressing surface.

5. The method as claimed in claim 1, wherein in the step of attaching the spacer formation layer to the semiconductor wafer, each of the support base and the spacer formation layer has such a size that the transparent substrate can be included within a region of the spacer where the removed support base was provided in the step of bonding the transparent substrate.

6. The method as claimed in claim 5, wherein the semiconductor wafer has a chamfered portion along an outer edge thereof, the chamfered portion formed by chamfering an outer portion of the semiconductor wafer, and
wherein in the step of attaching the spacer formation layer to the semiconductor wafer, the spacer formation layer is attached onto the semiconductor wafer so that an outer edge of the spacer formation layer is located on or near the chamfered portion.

7. The method as claimed in claim 5, wherein in the step of attaching the spacer formation layer to the semiconductor wafer, the spacer formation layer is attached onto the semiconductor wafer so that an outer edge of the spacer formation layer coincides with or is located beyond an outer edge of the semiconductor wafer.

8. The method as claimed in claim 1, wherein in the step of attaching the spacer formation layer to the semiconductor wafer, the spacer formation layer is attached onto the semiconductor wafer so that an outer edge of the spacer formation layer is located within an outer edge of the semiconductor wafer.

9. The method as claimed in claim 8, wherein in the step of bonding the transparent substrate, the transparent substrate is bonded to the spacer so that an outer edge of the transparent substrate is located within the outer edge of the spacer formation layer.

10. The method as claimed in claim 1, wherein the exposure is carried out by selectively irradiating the spacer formation layer with a chemical ray through the support base before the support base is removed, and the development is carried out after the support base has been removed.

11. The method as claimed in claim 1, wherein an average thickness of the support base is in the range of 5 to 100 μm.

12. The method as claimed in claim 1, wherein the spacer formation layer is formed of a material containing an alkali soluble resin, a thermosetting resin and a photo initiator.

13. The method as claimed in claim 12, wherein the alkali soluble resin is a (meth)acryl-modified phenol resin.

14. The method as claimed in claim 12, wherein the thermosetting resin is an epoxy resin.

15. A semiconductor wafer bonding product manufactured using the method defined by claim 1.

16. A semiconductor device obtained by dicing the semiconductor wafer bonding product defined by claim 15.
